(19) United States
(12) Patent Application Publication
(10) Pub. No.: US 2022/0356566 A1
(43) Pub. Date: Nov. 10, 2022

(54) SURFACE TREATMENT METHOD, REGION SELECTIVE FILM FORMATION METHOD FOR SUBSTRATE SURFACE, AND SURFACE TREATMENT AGENT

(71) Applicant: TOKYO OHKA KOGYO CO., LTD., Kawasaki-shi (JP)

(72) Inventors: Taiji NAKAMURA, Kawasaki-shi (JP); Kenji SEKI, Kawasaki-shi (JP); Jun IIOKA, Kawasaki-shi (JP)

(21) Appl. No.: 17/658,896

(22) Filed: Apr. 12, 2022

(30) Foreign Application Priority Data
Apr. 30, 2021 (JP) 2021-078033

(51) Int. Cl. C23C 16/40; C23C 16/455

(52) U.S. Cl. CPC C23C 16/403; C23C 16/45525

(57) ABSTRACT

A surface treatment method for the substrate surface including two or more regions, the method including reacting a compound having the formula R¹—P(═O)(OR²)(OR³), a basic nitrogen-containing compound, and the regions with each other such that a water contact angle on the metal region is greater by 10° or more with respect to a water contact angle on an insulator region close to the metal region. In compound (P-1), R¹ is an alkyl group, an alkoxy group, a fluorinated alkyl group or an optionally substituted aromatic hydrocarbon group and R² and R³ are each independently a hydrogen atom, an alkyl group, a fluorinated alkyl group or an optionally substituted aromatic hydrocarbon group.

This application claims priority to Japanese Patent Application No. 2021-078033, filed Apr. 30, 2021, the entire content of which is incorporated herein by reference.

### BACKGROUND OF THE INVENTION

### Field of the Invention

The present invention relates to a surface treatment method, a regional selective film formation method for a substrate surface, and a surface treatment agent.

### Related Art

In recent years, there has been a rising trend in the integration and miniaturization of semiconductor devices. Accordingly, a finer organic film patterned as a mask and a finer inorganic film patterned by etching treatment have been developed. Hence, it is required for the thicknesses of an organic film and an inorganic film formed on a semiconductor substrate to be controlled at an atomic layer level. An atomic layer deposition method (ALD (Atomic Layer Deposition) method; hereinafter also simply referred to as the “ALD method”) is known as a technique for forming a thin film on a substrate at an atomic layer level. It is known that as compared with a general CVD (Chemical Vapor Deposition) method, the ALD method has both high step coating (step coverage) and high film thickness control.

The ALD method is a thin film formation technique in which two types of gases having, as main components, elements of a film to be formed are alternately supplied onto a substrate to form a thin film on the substrate in atomic layer units, and this treatment is repeated a plurality of times to form a film having a desired thickness. In the ALD method, a growth self-control function (self-limit function) is utilized in which only the components of a raw material gas for forming one or several atomic layers are adsorbed to the surface of a substrate while the raw material gas is being supplied, whereas an extra amount of raw material gas does not contribute to the growth. For example, when an Al₂O₃ film is formed on a substrate, a raw material gas including TMA (TriMethyl Aluminum) and an oxidation gas containing oxygen is used. When a nitride film is formed on a substrate, a nitriding gas is used instead of the oxidation gas.

In recent years, a method for forming a film in a region selective way on the surface of a substrate has been attempted by utilization of the ALD method (see Patent Document 1 and Non-Patent Document 1). Accordingly, a substrate has been required to have a surface modified in a region selective manner to be suitably applied to the region selective film formation method on the substrate using the ALD method.
Patent Document 1: Japanese Unexamined Patent Application (Translation of PCT Application), Publication No. 2003-508897
Non-Patent Document 1: J. Phys. Chem. C 2014, 118, 10957-10962

### SUMMARY OF THE INVENTION

The present invention is made in view of the circumstances described above, and an object thereof is to provide a surface treatment method by which with respect to a substrate including, on the surface, a metal region and an insulator region close to each other, the metal region can be made water-repellent and the water repellency of the insulator region can be suppressed; a region selective film formation method for a substrate surface, the method including the surface treatment method described above; and a surface treatment agent suitable for use in the surface treatment method described above.

The present inventors have found to be able to achieve the object described above by using a surface treatment method for the surface of a substrate in which the surface includes two or more regions, the two or more regions include at least one metal region and at least one insulator region, at least one metal region described above and at least one insulator region described above in the two or more regions are close to each other, the metal region includes a metal, the insulator region includes one or more types of compounds selected from the group consisting of an oxide, a nitride, a carbide, a carbonitride, an oxynitride, an oxycarbonitride, and an insulating resin and a compound (P) that is a phosphorus compound having a specific structure, a basic nitrogen-containing compound (B) and the regions are caused to react with each other, and thereby have completed the present invention.

According to a first aspect of the present invention, there is provided a surface treatment method for the surface of a substrate, the surface including two or more regions, the two or more regions including at least one metal region and at least one insulator region, the at least one metal region and the at least one insulator region in the two or more regions being close to each other, the metal region including a metal, the insulator region including one or more types of compounds selected from the group consisting of an oxide, a nitride, a carbide, a carbonitride, an oxynitride, an oxycarbonitride, and an insulating resin, the surface treatment method including reacting a compound (P), a basic nitrogen-containing compound (B), and the regions with each other such that a water contact angle on the metal region is greater by 10° or more with respect to a water contact angle on the insulator region close to the metal region, the compound (P) being represented by a general formula (P-1) below:

R¹—P(═O)(OR²)(OR³) (P-1)

[in the formula, R¹ is an alkyl group, a fluorinated alkyl group, an alkoxy group, or an optionally substituted aromatic hydrocarbon group, and R² and R³ are each independently a hydrogen atom, an alkyl group, a fluorinated alkyl group or an optionally substituted aromatic hydrocarbon group].

According to a second aspect of the present invention, there is provided a region selective film formation method for a substrate surface, the region selective film formation method including: treating the substrate surface by the surface treatment method according to the first aspect; and forming a film by an atomic layer deposition method on the substrate surface subjected to the surface treatment, in which a larger amount of material of the film is deposited on the insulator region than on the metal region.

According to a third aspect of the present invention, there is provided a one-component surface treatment agent for use in the surface treatment method according to the first aspect, the one-component surface treatment agent including: the compound (P), the basic nitrogen-containing compound (B), and a solvent, the compound (P) being represented by the general formula (P-1) below:

R¹—P(═O)(OR²)(OR³) (P-1)

[in the formula, R¹ is an alkyl group, a fluorinated alkyl group, an alkoxy group or an optionally substituted aromatic hydrocarbon group and R² and R³ are each independently a hydrogen atom, an alkyl group, a fluorinated alkyl group, or an optionally substituted aromatic hydrocarbon group].

According to a fourth aspect of the present invention, there is provided a two-component surface treatment agent for use in the surface treatment method according to the first aspect, the two-component surface treatment agent including: a first surface treatment agent including the compound (P) and a solvent, and a second surface treatment agent including the basic nitrogen-containing compound (B) and a solvent, the compound (P) being represented by the formula (P-1) below:

R¹—P(═O)(OR²)(OR³) (P-1)

[in the formula, R¹ is an alkyl group, a fluorinated alkyl group, an alkoxy group, or an optionally substituted aromatic hydrocarbon group and R² and R³ are each independently a hydrogen atom, an alkyl group, a fluorinated alkyl group, or an optionally substituted aromatic hydrocarbon group].

According to the present invention, it is possible to provide a surface treatment method by which with respect to a substrate surface including a metal region and an insulator region close to each other, the metal region can be made water-repellent and the water repellency of the insulator region can be suppressed; a region selective film formation method for a substrate surface, the film formation method including the surface treatment method described above, and a surface treatment agent suitable for use in the surface treatment method described above.

### DETAILED DESCRIPTION OF THE INVENTION

### <Surface Treatment Method>

The surface treatment method is a surface treatment method for the surface of a substrate. The surface of the substrate includes two or more regions. The two or more regions include at least one metal region and at least one insulator region. At least one metal region described above and at least one insulator region described above in the two or more regions are close to each other. Here, that they are close to each other includes a case where at least one metal region described above and at least one insulator region described above are adjacent to each other so as to share a boundary line and a case where at least one metal region described above and at least one insulator region described above are located next to each other or separately so as not to share a boundary line. In the surface treatment method, a compound (P) and a basic nitrogen-containing compound (B) which will be described later and the regions described above are caused to react with each other such that a water contact angle on the metal region is greater by 10° or more with respect to a water contact angle on the insulator region close to the metal region.

### (Substrate and Substrate Surface)

In the surface treatment method, as the “substrate” serving as a target for surface treatment, substrates used for production of semiconductor devices are shown as examples. Examples of the substrate described above include a silicon (Si) substrate, a silicon nitride (SiN) substrate, a silicon oxide film (Ox) substrate, a tungsten (W) substrate, a cobalt (Co) substrate, a germanium (Ge) substrate, an aluminum (Al) substrate, a nickel (Ni) substrate, a ruthenium (Ru) substrate, a copper (Cu) substrate, a titanium nitride (TiN) substrate, a tantalum nitride (TaN) substrate, a silicon germanium (SiGe) substrate and the like. The “substrate surface” includes the surface of the substrate itself, the surface of an inorganic layer which is provided on the substrate and which is patterned, and the surface of an inorganic layer which is provided on the substrate and which is not patterned. The surface of the inorganic layer which is patterned substantially includes side surfaces of the pattern.

As the inorganic layer which is provided on the substrate and which is patterned, an inorganic layer in which an etching mask is produced by a photoresist method on the surface of the inorganic layer present on the substrate and which is thereafter formed and patterned by etching treatment and an inorganic layer which is formed and patterned by an atomic layer deposition method (ALD method) on the surface of the substrate are shown as examples. Even when an inorganic layer which is formed and patterned by the ALD method on the surface of the substrate is obtained, the surface treatment agent of the present invention can be used. The surface treatment agent of the present invention is used, and thus it is possible to ensure the selectivity of a region corresponding to the metal region and a region corresponding to the insulator region serving as the inorganic layer. Examples of the inorganic layer include a substrate itself, an oxidation film of elements that make up the substrate, a silicon nitride film (SiN) and a silicon oxide film (SiOx) formed on the surface of the substrate, films or layers of inorganic substances such as tungsten (W), cobalt (Co), germanium (Ge), aluminum (Al), nickel (Ni), ruthenium (Ru), copper (Cu), silver (Ag), titanium (Ti), gold (Au), chromium (Cr), molybdenum (Mo), aluminum oxide (Al₂O₃), titanium oxide (TiO₂), zirconium oxide (ZrO₂), hafnium oxide (HfO₂), tantalum oxide (Ta₂O₅), titanium nitride (TiN), tantalum nitride (TaN), silicon germanium (SiGe), silicon oxide (SiO₂) and the like. Although the films and layers as described above are not particularly limited, films and layers of inorganic substances formed in the process of producing semiconductor devices and the like are shown as examples. As the inorganic layer which is provided on the substrate and is not patterned, films and layers of inorganic substances which are provided on the substrate, are patterned and are made of the same material as the inorganic layer described above and the like are shown as examples.

### (Metal Region and Insulator Region)

The metal region is made of a metal or a conductive metal-containing compound. The metal region may be defined as a conductor region for the insulator region which will be described later. As the metal or the conductive metal-containing compound, among the inorganic substances described above, copper (Cu), cobalt (Co), aluminum (Al), silver (Ag), nickel (Ni), titanium (Ti), gold (Au), chromium (Cr), molybdenum (Mo), tungsten (W), ruthenium (Ru), titanium nitride (TiN), tantalum nitride (TaN) and the like are preferable. The insulator region is made of one or more types of compounds selected from the group consisting of an oxide, a nitride, a carbide, a carbonitride, an oxynitride, an oxycarbonitride and an insulating resin, and an oxide, a nitride, a carbide, a carbonitride, an oxynitride and an oxycarbonitride are preferable. As the oxide, aluminum oxide (Al₂O₃), titanium oxide (TiO₂), zirconium oxide (ZrO₂), hafnium oxide (HfO₂), tantalum oxide (Ta₂O₅), silicon oxide (SiOx (1≤X≤2)), fluorine-containing silicon oxide (SiOF) and carbon-containing silicon oxide (SiOC) are preferable. As the nitride, for example, silicon nitride (SiN) and boron nitride (BN) are preferable. As the carbide, silicon carbide (SiC) is preferable. As the carbonitride, silicon nitride (SICN) is preferable. As the oxynitride, silicon nitride (SiON) is preferable. As the oxycarbonitride, acidic silicon nitride (SiOCN) is preferable. Examples of the insulating resin include polyimide, polyester, plastic resin and the like.

In the surface treatment method, the water contact angle on the metal region is greater by 10° or more with respect to the water contact angle on the insulator region close to the metal region. This indicates that the metal region is made water-repellent and the water repellency of the insulator region is suppressed.

(Embodiment in which the Substrate Surface Including Two Regions)

As an embodiment in which the substrate surface includes two regions, for example, an embodiment can be exemplified in which one of the two regions is the metal region serving as a first region and a region close to the region described above is the insulator region serving as a second region. Here, each of the first region and the second region may be or may not be divided into a plurality of regions. Examples of the first region and the second region include: an embodiment in which the substrate surface itself is the metal region serving as the first region and a layer which is formed on the substrate surface and which includes an insulator is the insulator region serving as the second region; an embodiment in which the substrate surface itself is the insulator region serving as the first region and a layer which is formed on the substrate surface and which includes a metal is the metal region serving as the second region; an embodiment in which a layer which is formed on the substrate surface and which includes a metal is the metal region serving as the first region and a layer which is formed on the substrate surface and which includes an insulator is the insulator region serving as the second region; and an embodiment in which part of the surface of the substrate which is an insulator is the metal region serving as the first region and a layer that is formed on at least part of the surface of the substrate other than the metal region described above and that includes an insulator and/or at least part of the surface of the substrate other than the metal region described above (or all the surface of the substrate other than the metal region) is the insulator region serving as the second region.

(Embodiment in which Substrate Surface Includes Three or More Regions)

As an embodiment in which the substrate surface includes three or more regions, the following embodiments can be exemplified: an embodiment in which one of the two or more regions is the metal region serving as a first region, a region close to the region described above is the insulator region serving as a second region, and a region close to the second insulator region is the metal region serving as a third region; and an embodiment in which one of the two or more regions is the insulator region serving as the first region, a region close to the region described above is the metal region serving as the second region, and a region close to the second metal region is the insulator region serving as the third region.

Here, the first region and the third region differ from each other in material. Each of the first region, the second region and the third region may be or may not be divided into a plurality of regions. Examples of the first region, the second region and the third region include: an embodiment in which the substrate surface itself is the metal region serving as the first region, the surface of the insulator region which is close to the substrate and which is formed on the substrate surface is the second region and the surface of the metal region which is close to the second region and which is formed on the substrate surface is the third region; an embodiment in which the surface of the substrate itself is the insulator region serving as the first region, the surface of the metal region which is close to the substrate and which is formed on the substrate surface is the second region, and the surface of the insulator region which is close to the second region and which is formed on the substrate surface is the third region; and the like. The same concept can be applied to a case where four or more regions are present. Although the upper limit of the number of regions which differ in material is not limited as long as the effects of the present invention are not impaired, the number of regions is, for example, equal to or less than 7 or equal to or less than 6, and is typically equal to or less than 5.

### (Compound (P))

In the surface treatment method, the compound (P) represented by a general formula (P-1) below is caused to react with the regions described above,

R¹—P(═O)(OR²)(OR³) (P-1)

[in the formula, R¹ is an alkyl group, an alkoxy group, a fluorinated alkyl group or an optionally substituted aromatic hydrocarbon group and R² and R³ are each independently a hydrogen atom, an alkyl group, a fluorinated alkyl group, or an optionally substituted aromatic hydrocarbon group].

In the compound (P) represented by the formula (P-1), as the alkyl group serving as R¹, a linear or branched-chain alkyl group having 8 or more carbon atoms is preferable, and a linear or branched-chain alkyl group having 12 or more carbon atoms is more preferable.

Preferred specific examples of the alkyl group serving as R¹ include an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group, and alkyl groups having structural isomerism with the alkyl groups described above.

In the compound (P) represented by the formula (P-1), as the alkoxy group serving as R¹, a linear or branched-chain alkoxy group having 8 or more carbon atoms is preferable, and a linear or branched-chain alkoxy group having 12 or more carbon atoms is more preferable.

Preferred specific examples of the alkoxy group serving as R¹ include an octyloxy group, a nonyloxy group, a decyloxy group, an undecyloxy group, a dodecyloxy group, a tridecyloxy group, an isotridecyloxy group, a tetradecyloxy group, a pentadecyloxy group, a hexadecyloxy group, an isohexadecyloxy group, a heptadecyloxy group, an octadecyloxy group, a nonadecyloxy group, an icosyloxy group, a henicosyloxy group and a docosyloxy group, and alkoxy groups having structural isomerism with the alkoxy groups described above.

In the compound (P) represented by the formula (P-1), as the fluorinated alkyl group serving as R¹, a linear or branched-chain fluorinated alkyl group having 8 or more carbon atoms is preferable, and a linear or branched-chain fluorinated alkyl group having 12 or more carbon atoms is more preferable.

Preferred specific examples of the fluorinated alkyl group serving as R¹ include groups in which part or all of hydrogen atoms in the alkyl group serving as R¹ illustrated above are substituted with fluorine atoms.

Examples of the aromatic hydrocarbon group which may include the substituent serving as R¹ in the compound (P) represented by the formula (P-1) include a phenyl group, a naphthyl group, an anthryl group, a p-methylphenyl group, a p-tert-butylphenyl group, a p-adamantylphenyl group, a tolyl group, an xylyl group, a cumenyl group, a mesityl group, a biphenyl group, a phenanthryl group, a 2,6-diethylphenyl group and a 2-methyl-6-ethylphenyl group.

Although in the compound (P) represented by the formula (P-1), the upper limit of the number of carbon atoms included in the substituent serving as R¹ described above is not particularly limited, the number of carbon atoms is, for example, 45 or less.

In the compound (P) represented by the formula (P-1), as the alkyl group serving as R² and R³, a linear or branched-chain alkyl group having 8 or more carbon atoms is preferable.

Preferred specific examples of the alkyl group serving as R² and R³ include an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group, and alkyl groups having structural isomerism with the alkyl groups described above.

In the compound (P) represented by the formula (P-1), as the fluorinated alkyl group serving as R² and R³, a linear or branched-chain fluorinated alkyl group having 8 or more carbon atoms is preferable.

Preferred specific examples of the fluorinated alkyl group serving as R² and R³ include groups in which part or all of hydrogen atoms in the alkyl group serving as R² and R³ illustrated above are substituted with fluorine atoms.

Examples of the aromatic hydrocarbon group which may include the substituent serving as R² and R³ in the compound (P) represented by the formula (P-1) include a phenyl group, a naphthyl group, an anthryl group, a p-methylphenyl group, a p-tert-butylphenyl group, a p-adamantylphenyl group, a tolyl group, an xylyl group, a cumenyl group, a mesityl group, a biphenyl group, a phenanthryl group, a 2,6-diethylphenyl group and a 2-methyl-6-ethylphenyl group.

Among them, as R² and R³, hydrogen atoms are preferable.

As the compound (P), one type may be used singly or two or more types may be used.

### (Basic Nitrogen-Containing Compound (B))

In the surface treatment method, the basic nitrogen-containing compound (B) is caused to react with the regions described above.

The basic nitrogen-containing compound (B) means a compound which suppresses the water repellency of the insulator region caused by the compound (P). Although the cause of the property of the basic nitrogen-containing compound (B) as described above is not clear, it is estimated that this is because the cation species of the basic nitrogen-containing compound (B) is adsorbed to the insulator region to inhibit the adsorption of the compound (P) to the insulator region. Although the basic nitrogen-containing compound (B) is not particularly limited as long as the basic nitrogen-containing compound (B) has the property as described above, examples thereof include a quaternary ammonium compound, a pyridinium halide, a pyrrolidinium halide, a bipyridinium halide and an amine having pK_{b} of 2.5 or less or a salt thereof (hereinafter also referred to as the “low pK_{b} amine”).

As the quaternary ammonium compound, for example, a quaternary ammonium salt represented by a formula (b1) below is mentioned.

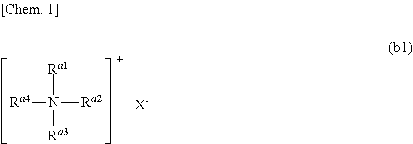

In the formula (b1), R^{a1} to R^{a4} respectively and independently represent an alkyl group having 1 to 16 carbon atoms, an aryl group having 6 to 16 carbon atoms, an aralkyl group having 7 to 16 carbon atoms and a hydroxyalkyl group having 1 to 16 carbon atoms. At least two of R^{a1} to R^{a4} may be combined with each other to form a cyclic structure, and in particular, at least one of the combination of R^{a1} and R^{a2} and the combination of R^{a3} and R^{a4} may be combined with each other to form a cyclic structure. In the formula (b1), X⁻ represents an organic carboxylic acid ion which may include a hydroxide ion, a chloride ion, a fluoride ion or fluorine. Examples of the organic carboxylic acid ion which may include fluorine include an acetate ion, a trifluoroacetic acid ion and the like.

Among the compounds represented by the formula (b1), the hydroxides, the chlorides and the fluorides of tetramethylammonium, tetraethylammonium, tetrapropylammonium, tetrabutylammonium, methyltripropylammonium, methyltributylammonium, ethyltrimethylammonium, dimethyldiethylammonium salt, benzyltrimethylammonium, hexadecyltrimethylammonium, (2-hydroxyethyl) trimethylammonium and spiro-(1,1′)-bipyrrolidinium are preferable in terms of availability, the hydroxides and the fluorides are more preferable in terms of the effects of the present invention and the hydroxides and the fluorides of tetramethylammonium and benzyltrimethylammonium are further preferable. As the pyridinium halide, the chloride and the fluoride of pyridinium are mentioned, and the fluoride is preferable. As the pyrrolidinium halide, the chloride and the fluoride of pyrrolidinium are mentioned, and the fluoride is preferable. As the bipyridinium halide, the chloride and the fluoride of bipyridinium are mentioned, and the fluoride is preferable.

The pK_{b} of the low pK_{b} amine is preferably equal to or less than 2.0 and more preferably equal to or less than 1.5. As the low pK_{b} amine, for example, a guanidine derivative is mentioned.

Examples of the guanidine derivative include methylguanidine, dimethylguanidine, trimethylguanidine, tetramethylguanidine, the chloride salts thereof and the fluoride salts thereof. Among them, tetramethylguanidine and the chloride salt thereof are preferable.

### (Reaction)

In the surface treatment method, the compound (P) and the basic nitrogen-containing compound (B) are caused to react with the surface of the substrate including the metal region and the insulator region. As a method for causing these compounds to react with the surface of the substrate, a method using a one-component surface treatment agent containing the compound (P), the basic nitrogen-containing compound (B) and a solvent and a method using a two-component surface treatment agent including a first surface treatment agent containing the compound (P) and a solvent and a second surface treatment agent containing the basic nitrogen-containing compound (B) and a solvent are mentioned. As the surface treatment method, a method for exposing the surface treatment agent described above to the surface of the substrate by a means of a coating method such as an immersion method, a spin coat method, a roll coat method or a doctor blade method is mentioned.

In terms of the water repellency of the metal region, the content of the compound (P) in the total mass of the one-component surface treatment agent is preferably equal to or greater than 0.001% by mass and equal to or less than 5% by mass, more preferably equal to or greater than 0.005% by mass and equal to or less than 4% by mass, further preferably equal to or greater than 0.01% by mass and equal to or less than 3% by mass and particularly preferably equal to or greater than 0.03% by mass and equal to or less than 3% by mass. In terms of the water repellency of the metal region, the content of the compound (P) in the total mass of the first surface treatment agent in the two-component surface treatment agent is preferably equal to or greater than 0.001% by mass and equal to or less than 5% by mass, more preferably equal to or greater than 0.005% by mass and equal to or less than 4% by mass, further preferably equal to or greater than 0.01% by mass and equal to or less than 3% by mass and particularly preferably equal to or greater than 0.03% by mass and equal to or less than 3% by mass.

In terms of suppressing the water repellency of the insulator region, the content of the basic nitrogen-containing compound (B) in the total mass of the one-component surface treatment agent is preferably equal to or greater than 0.0001% by mass and equal to or less than 5% by mass, more preferably equal to or greater than 0.001% by mass and equal to or less than 4% by mass, further preferably equal to or greater than 0.005% by mass and equal to or less than 3% by mass and particularly preferably equal to or greater than 0.01% by mass and equal to or less than 3% by mass. In terms of suppressing the water repellency of the insulator region, the content of the basic nitrogen-containing compound (B) in the total mass of the second surface treatment agent in the two-component surface treatment agent is preferably equal to or greater than 0.0001% by mass and equal to or less than 5% by mass, more preferably equal to or greater than 0.001% by mass and equal to or less than 4% by mass, further preferably equal to or greater than 0.005% by mass and equal to or less than 3% by mass and particularly preferably equal to or greater than 0.01% by mass and equal to or less than 3% by mass.

Examples of the solvent include sulfoxides, sulfones, amides, lactams, imidazolidinones, dialkyl glycol ethers, monoalcohol solvents, (poly)alkylene glycol monoalkyl ethers, (poly)alkylene glycol monoalkyl ether acetates, other ethers, ketones, other esters, lactones, linear, branched and cyclic aliphatic hydrocarbons, aromatic hydrocarbons, terpenes and the like.

Examples of the sulfoxides include dimethyl sulfoxide.

Examples of the sulfones include dimethyl sulfone, diethyl sulfone, bis(2-hydroxyethyl) sulfone and tetramethylene sulfone.

Examples of the amides include N,N-dimethylformamide, N-methylformamide, N,N-dimethylacetamide, N-methylacetamide and N,N-diethylacetamide.

Examples of the lactams include N-methyl-2-pyrrolidone, N-ethyl-2-pyrrolidone, N-propyl-2-pyrrolidone, N-hydroxymethyl-2-pyrrolidone and N-hydroxyethyl-2-pyrrolidone.

Examples of the imidazolidinones include 1,3-dimethyl-2-imidazolidinone, 1,3-diethyl-2-imidazolidinone and 1,3-diisopropyl-2-imidazolidinone.

Examples of the dialkyl glycol ethers include dimethyl glycol, dimethyldiglycol, dimethyltriglycol, methylethyldiglycol, diethylglycol and triethylene glycol butylmethyl ether.

Examples of the monoalcohol solvents include methanol, ethanol, n-propanol, isopropanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, sec-heptanol, 3-heptanol, 1-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol and cresol.

Examples of the (poly)alkylene glycol monoalkyl ethers include ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropropylene glycol monoethyl ether, dipropylene glycol mono-n-propyl ether, dipropylene glycol mono-n-butyl ether, tripropylene glycol monomethyl ether and tripropylene glycol monoethyl ether.

Examples of the (poly)alkylene glycol monoalkyl ether acetates include ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, propylene glycol monomethyl ether acetate and propylene glycol monoethyl ether acetate.

Examples of the other esters include dimethyl ether, diethyl ether, methyl ethyl ether, dipropyl ether, diisopropyl ether, dibutyl ether, diisoamyl ether, diethylene glycol dimethyl ether, diethylene glycol methyl ethyl ether, diethylene glycol diethyl ether, tetraethylene glycol dimethyl ether and tetrahydrofuran.

Examples of the ketones include methyl ethyl ketone, cyclohexanone, 2-heptanone and 3-heptanone.

Examples of the other esters include lactic acid alkyl esters such as methyl 2-hydroxypropionate and ethyl 2-hydroxypropionate, ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methoxybutyl acetate, 3-methyl-3-methoxy-1-butyl-acetate, 3-methyl-3-methoxybutyl propionate, ethyl acetate, n-propyl acetate, isopropyl acetate, n-butyl acetate, isobutyl acetate, n-pentyl acetate, n-hexyl acetate, n-heptyl acetate, n-octyl acetate, n-pentyl formate, isopentyl acetate, n-butyl propionate, ethyl butyrate, n-propyl butyrate, isopropyl butyrate, n-butyl butyrate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate and propylene glycol diacetate.

Examples of the lactones include propyrolactone, γ-butyrolactone and 6-pentillolactone.

Examples of the linear, branched and cyclic aliphatic hydrocarbons include n-hexane, n-heptane, n-octane, n-nonane, methyloctane, n-decane, n-undecane, n-dodecane, 2,2,4,6,6-pentamethylheptane, 2,2 4,4,6,8,8-heptane methyl nonane, cyclohexane and methylcyclohexane.

Examples of the aromatic hydrocarbons include benzene, toluene, xylene, 1,3,5-trimethylbenzene and naphthalene.

Examples of the terpenes include p-menthane, diphenylmentan, limonene, terpinene, bornane, norbornane and pinan.

Among them, as the solvent, 3-methyl-3-methoxy-1-butyl acetate, ethyl acetate, propylene glycol monomethyl ether acetate, propylene glycol monomethyl ether, diethylene glycol monomethyl ether, 1-octanol and methyl ethyl ketone are preferable, and propylene glycol monomethyl ether and 1-octanol are more preferable.

Examples of other components which can be mixed with the surface treatment agent include a pH regulator, an antioxidant, a UV absorber, a viscosity regulator and a defoamer.

The pH of the one-component surface treatment agent and the pH of the second surface treatment agent in the two-component surface treatment agent are preferably equal to or greater than 5 and more preferably equal to or greater than 8. The basic nitrogen-containing compound (B) used in the present invention is contained, and thus the pH of the one-component surface treatment agent and the pH of the second surface treatment agent in the two-component surface treatment agent have the preferred pH range described above. Hence, it is generally unnecessary to provide a component other than the essential components described above in order to regulate the pH to the preferred pH described above,

The exposure temperature is, for example, equal to or greater than 10° C. and equal to or less than 90° C., preferably equal to or greater than 20° C. and equal to or less than 80° C., more preferably equal to or greater than 20° C. and equal to or less than 70° C. and further preferably equal to or greater than 20° C. and equal to or less than 30° C. In terms of the water repellency of the metal region and the suppression of the water repellency of the insulator region, the exposure time is preferably equal to or greater than 20 seconds, more preferably equal to or greater than 30 seconds and further preferably equal to or greater than 45 seconds. Although the upper limit of the exposure time is not particularly limited, the exposure time is, for example, equal to or less than 2 hours, typically equal to or less than 1 hour, preferably equal to or less than 15 minutes, further preferably equal to or less than 5 minutes and particularly preferably equal to or less than 2 minutes. After the exposure described above, as necessary, cleaning and/or drying may be performed. The cleaning is performed by water rinse, activator rinse or the like. The drying is performed by nitrogen blow or the like.

By the reaction with the regions described above, the compound (P) can be selectively adsorbed to the metal region of the metal region and the insulator region close to each other. Consequently, a water contact angle on the metal region can be greater by 10° or more with respect to a water contact angle on the insulator region close to the metal region, preferably greater by 15° or more, more preferably greater by 20° or more and further preferably greater by 25° or more. The contact angle with water on the surface of the substrate after being exposed to the surface treatment agent can be, for example, equal to or greater than 50° and equal to or less than 140°. The material of the surface of the substrate, the type and amount of surface treatment agent used, exposure conditions and the like are controlled, and thus the water contact angle can be equal to or greater than 50°, preferably equal to or greater than 60°, more preferably equal to or greater than 70° and further preferably equal to or greater than 90°. Although the upper limit of the contact angle is not particularly limited, the contact angle is, for example, equal to or less than 140° and typically equal to or less than 130°. More specifically, the water contact angle on the metal region is preferably equal to or greater than 70°, more preferably equal to or greater than 80°, much more preferably equal to or greater than 90° and further preferably equal to or greater than 100°. Although the upper limit of the contact angle is not particularly limited, the contact angle is, for example, equal to or less than 140°. The water contact angle on the insulator region is preferably equal to or less than 70°, more preferably equal to or less than 65° and much more preferably equal to or less than 60°. Although the lower limit of the contact angle is not particularly limited, the contact angle is, for example, equal to or less than 50°.

### <Regionally Selective Film Formation Method for Surface of Substrate>

A regionally selective film formation method for the surface of the substrate using the surface treatment method described above will be described next. The regionally selective film formation method for the surface of the substrate includes: treating the surface of the substrate by the surface treatment method described above; and forming a film on the surface of the substrate subjected to the surface treatment by the atomic layer deposition method (ALD method), and a larger amount of material of the film is deposited on the insulator region than on the metal region.

As a result of the surface treatment described above, the water contact angle on the metal region can be greater by 10° or more with respect to the water contact angle on the insulator region close to the metal region. In the metal region where the water contact angle is larger than on the insulator region, the material for the film formation using the ALD method is unlikely to be adsorbed to the region described above on the surface of the substrate. Consequently, an ALD cycle is repeated, and thus the thickness of the film on the insulator region can be selectively increased.

### (Film Formation Using ALD Method)

Although the film formation method using the ALD method is not particularly limited, a thin film formation method by adsorption using at least two gas phase reactants (hereinafter simply referred to as “precursor gases”) is preferably used. The adsorption using the precursor gases is preferably chemisorption. Specifically, a method which includes steps (a) and (b) below and repeats the steps (a) and (b) below at least once (one cycle) until the desired film thickness is obtained and the like are mentioned:

(a) a step of exposing, to the pulse of the first precursor gas, the substrate subjected to the surface treatment by the method according to the second aspect described above; and
(b) a step of exposing the substrate to the pulse of the second precursor gas after the step (a).

During a period between the step (a) and the step (b), a plasma treatment step, a step of removing or discharging (purging) the first precursor gas and the resulting reactant with a carrier gas, the second precursor gas or the like or another step may be or may not be included. After the step (b), a plasma treatment step, a step of removing or purging the second precursor gas and the resulting reactant with a carrier gas or the like or another step may be or may not be included. Examples of the carrier gas include inert gases such as nitrogen gas, argon gas and helium gas.

Each pulse per cycle and each layer formed per cycle are preferably subjected to self-control, and each layer formed is more preferably a monoatomic layer. The film thickness of the monoatomic layer can be, for example, equal to or less than 5 nm, preferably equal to or less than 3 nm, more preferably equal to or less than 1 nm and further preferably equal to or less than 0.5 nm.

Examples of the first precursor gas include an organic metal, a metal halide, a metal oxide halide and the like, and specific examples thereof include tantalum pentaethoxydo, tetrakis (dimethylamino) titanium, pentax (dimethylamino) tantalum, tetrakis (dimethylamino) zirconium, tetrakis (dimethylamino) hafnium, tetrakis (dimethylamino) silane, copper hexafluoroacetylacetonate vinyltrimethylsilane, Zn(C₂H₅)₂, Zn(CH₃)₂, TMA (trimethylaluminum), TaCl₅, WF₆, WOCl₄, CuCl, ZrCl₄, AlCl₃, TiCl₄, SiCl₄, HfCl₄ and the like.

Examples of the second precursor gas include a precursor gas capable of decomposing the first precursor and a precursor gas capable of removing the ligand of the first precursor, and specific examples thereof include H₂O, H₂O₂, O₂O₃, NH₃, H₂S, H₂Se, PH₃, AsH₃, C₂H₄, Si₂H₆ and the like.

Although the exposure temperature in the step (a) is not particularly limited, the exposure temperature is, for example, equal to or greater than 100° C. and equal to or less than 800° C., preferably equal to or greater than 150° C. and equal to or less than 650° C., more preferably equal to or greater than 200° C. and equal to or less than 500° C. and further preferably equal to or greater than 225° C. and equal to or less than 375° C.

Although the exposure temperature in the step (b) is not particularly limited, the exposure temperature in the step (b) is, for example, substantially equal to the exposure temperature in the step (a) or greater than the exposure temperature in the step (a). Although the film formed by the ALD method is not particularly limited, examples thereof include films containing pure elements (for example, Si, Cu, Ta and W), films containing oxides (for example, SiO₂, GeO₂, HfO₂, ZrO₂, Ta₂O₅, TiO₂, Al₂O₃, ZnO, SnO₂, Sb₂O₅, B₂O₃, In₂O₃ and WO₃), films containing nitrides (for example, Si₃N₄, TiN, AlN, BN, GaN and NbN), films containing carbides (for example, SiC), films containing sulfides (for example, CdS, ZnS, MnS, WS₂ and PbS), films containing selenides (for example, CdSe and ZnSe), films containing phosphides (for example, GaP and InP), films containing arsenides (for example, GaAs and InAs), mixtures thereof and the like.

### <Surface Treatment Agent>

The surface treatment agent used in the surface treatment method described above will be described next. The surface treatment agent is a one-component surface treatment agent which contains the compound (P) represented by a general formula (P-1) below, the basic nitrogen-containing compound (B) and a solvent. As another form, the surface treatment agent is a two-component surface treatment agent which includes: the first surface treatment agent containing the compound (P) represented by the general formula (P-1) below and a solvent; and the second surface treatment agent containing the basic nitrogen-containing compound (B) and a solvent. Even when either of the one-component surface treatment agent and the two-component surface treatment agent is used to treat the surface of the substrate, it is possible to make the metal region water-repellent and suppress the water repellency of the insulator region. As long as the desired effects are obtained, the surface treatment agent may contain components (hereinafter also referred to “other components”) other than the compound (P), the basic nitrogen-containing compound (B) and the solvent. Components which can be contained in the one-component surface treatment agent and the two-component surface treatment agent, components which are essential and arbitrary components will be described below.

### (Compound (P))

The compound (P) is represented by the general formula (P-1) below:

R¹—P(═O)(OR²)(OR³) (P-1)

[in the formula, R¹ is an alkyl group, an alkoxy group, a fluorinated alkyl group, or an optionally substituted aromatic hydrocarbon group and R² and R³ are each independently a hydrogen atom, an alkyl group, a fluorinated alkyl group, or an optionally substituted aromatic hydrocarbon group].

The compound (P) represented by the formula (P-1) described above is the same as the above-described compound (P) contained in the surface treatment agent used in the surface treatment method described above.

As the compound (P), one type may be used singly or two or more types may be used. In terms of the water repellency of the metal region, the content of the compound (P) in the total mass of the one-component surface treatment agent is preferably equal to or greater than 0.001% by mass and equal to or less than 5% by mass, more preferably equal to or greater than 0.005% by mass and equal to or less than 4% by mass, further preferably equal to or greater than 0.01% by mass and equal to or less than 3% by mass and particularly preferably equal to or greater than 0.03% by mass and equal to or less than 3% by mass. In terms of the water repellency of the metal region, the content of the compound (P) in the total mass of the first surface treatment agent in the two-component surface treatment agent is preferably equal to or greater than 0.001% by mass and equal to or less than 5% by mass, more preferably equal to or greater than 0.005% by mass and equal to or less than 4% by mass, further preferably equal to or greater than 0.01% by mass and equal to or less than 3% by mass and particularly preferably equal to or greater than 0.03% by mass and equal to or less than 3% by mass.

### (Basic Nitrogen-Containing Compound (B))

The basic nitrogen-containing compound (B) is the same as the above-described basic nitrogen-containing compound (B) included in the surface treatment agent used in the surface treatment method described above.

As the basic nitrogen-containing compound (B), one type may be used singly or two or more types may be used. In terms of suppressing the water repellency of the insulator region, the content of the basic nitrogen-containing compound (B) in the total mass of the one-component surface treatment agent is preferably equal to or greater than 0.0001% by mass and equal to or less than 5% by mass, more preferably equal to or greater than 0.001% by mass and equal to or less than 4% by mass, further preferably equal to or greater than 0.005% by mass and equal to or less than 3% by mass and particularly preferably equal to or greater than 0.01% by mass and equal to or less than 3% by mass. In terms of suppressing the water repellency of the insulator region, the content of the basic nitrogen-containing compound (B) in the total mass of the second surface treatment agent in the two-component surface treatment agent is preferably equal to or greater than 0.0001% by mass and equal to or less than 5% by mass, more preferably equal to or greater than 0.001% by mass and equal to or less than 4% by mass, further preferably equal to or greater than 0.005% by mass and equal to or less than 3% by mass and particularly preferably equal to or greater than 0.01% by mass and equal to or less than 3% by mass.

### (Solvent)

The solvent is the same as the above-described solvent included in the surface treatment agent used in the surface treatment method described above.

### (Other Components)

Examples of the other components include a pH regulator, an antioxidant, a UV absorber, a viscosity regulator and a defoamer.

The surface treatment agent is obtained by mixing the compound (P), the compound (S), the solvent and the other components as necessary by a known method.

The pH of the one-component surface treatment agent and the pH of the second surface treatment agent in the two-component surface treatment agent are preferably equal to or greater than 5 and more preferably equal to or greater than 8. The basic nitrogen-containing compound (B) used in the present invention is contained, and thus the pH of the one-component surface treatment agent and the pH of the second surface treatment agent in the two-component surface treatment agent have the preferred pH range described above. Hence, it is generally unnecessary to provide a component other than the essential components described above in order to regulate the pH to the preferred pH described above.

As a method for using the one-component surface treatment agent, for example, a method for causing the one-component surface treatment agent to react with the surface of the substrate including the metal region and the insulator region is mentioned. As a reaction method, for example, a method for exposing the one-component surface treatment agent to the surface of the substrate by a means of a coating method such as an immersion method, a spin coat method, a roll coat method or a doctor blade method is mentioned. Reaction conditions such as the exposure temperature are the same as the conditions in the surface treatment method described above. As a method for using the two-component surface treatment agent, for example, a method for causing the two-component surface treatment agent to react with the surface of the substrate including the metal region and the insulator region and then causing the one-component surface treatment agent to react with the surface of the substrate including the metal region and the insulator region is mentioned. By the methods described above, it is possible to make the metal region water-repellent and suppress the water repellency of the insulator region.

### EXAMPLES

Although the present invention will be more specifically described below based on Examples and Comparative Examples, the present invention is not limited to the Examples below.

### Examples 1 to 4 and Comparative Examples 1 to 3

### (Preparation of Surface Treatment Agent)

The contents of the compound (P) and the basic nitrogen-containing compound (B) described in table 1 below were evenly mixed with a solvent below to prepare surface treatment agents for Examples 1 to 4 and Comparative Examples 1 to 3. As the compound (P), P1 below was used.

P1: Octadecylphosphonic acid
As the basic nitrogen-containing compound (B), B1 to B6 below were used.
B2: Triethylamine (pK_{b}=3.85)
B3: Pyrrolidine (pK_{b}=3.03)
B4: 1,1,3,3-tetramethylguanidine (pK_{b}=1.24)
B5: Tetramethylammonium hydroxide
B6: Benzyltrimethylammonium hydroxide
In Example 2, a propylene glycol solution containing 15% by mass of B5 was used, in Example 3, an aqueous solution containing 25% by mass of B5 was used and in Example 4, an ethanol solution containing 40% by mass of B6 was used.
As the solvent, A1 below was used.
A1: Propylene glycol monomethyl ether

### (Pretreatment, Surface Treatment)

The surface treatment agents obtained in Examples 1 to 4 and Comparative Examples 1 to 3 were used, and thus surface treatment was performed on an Al₂O₃ substrate and a Cu substrate according to the following method. Specifically, pretreatment was performed by immersing each of the substrates in an HF aqueous solution having a concentration of 25 ppm at 25° C. for 10 minutes. After the pretreatment described above, cleaning was performed on each of the substrates with deionized water for one minute. Each of the substrates after being washed with water was dried with nitrogen flow. The surface treatment was performed on each of the substrates by immersing each of the substrate after being dried in the corresponding surface treatment agent at 25° C. for 1 minute. Each of the substrates after the surface treatment was cleaned with isopropanol for one minute, and was then cleaned with deionized water for one minute. Each of the substrates after being cleaned was dried with nitrogen flow, and thus the substrates subjected to the surface treatment were obtained.

### (Measurement of Water Contact Angle)

For each of the substrates after the surface treatment, a water contact angle was measured. In the measurement of the water contact angle, Dropmaster 700 (made by Kyowa Interface Science Co., Ltd.) was used, pure water droplets (2.0 μL) were dropped on the surface of each of the substrates and the contact angle two seconds after the dropping was measured. A “difference in water contact angle” obtained by subtracting the water contact angle on the Al₂O₃ substrate from the water contact angle on the Cu substrate was calculated. The results are shown in table 1.

TABLE 1

| | Compound | Compound | | Water | | Difference |
|---|---|---|---|---|---|---|
| | (P) | (B) | | contact | | in water |
| | Type/ | Type/ | Solvent | angle (°) | | contact |
| | mass % | mass % | Type | Al₂O₃ | Cu | angle (°) |
| Comparative | P1/0.05 | 0 | A1 | 108.3 | 104.7 | −3.6 |
| Example 1 | | | | | | |
| Comparative | P1/0.05 | B2/0.051 | A1 | 97.5 | 98.5 | 1.0 |
| Example 2 | | | | | | |
| Comparative | P1/0.05 | B3/0.036 | A1 | 93.6 | 90.8 | −2.8 |
| Example 3 | | | | | | |
| Example 1 | P1/0.05 | B4/0.058 | A1 | 73.1 | 86.3 | 13.2 |
| Example 2 | P1/0.05 | B5/0.046 | A1 | 58.7 | 91.0 | 32.3 |
| Example 3 | P1/0.05 | B5/0.046 | A1 | 53.6 | 92.9 | 39.3 |
| Example 4 | P1/0.05 | B6/0.084 | A1 | 50.4 | 88.9 | 38.5 |

It is found from table 1 that when the surface treatment was performed on each of the substrates with the surface treatment agents in Comparative Examples 1 to 3, the maximum of the difference in water contact angle was only 1.0° in Comparative Example 2. On the other hand, when the surface treatment agent in Example 1 was used, the difference in water contact angle exceeded 10°. In Example 1 and Comparative Examples 1 to 3, the water contact angle of Cu was substantially the same. It is found from the results of these tests that an amine having pK_{b} of 2.5 or less was used as the basic nitrogen-containing compound (B) together with the compound (P), thus the difference in water contact angle was 10° or less and consequently, the water repellency of the Al₂O₃ substrate serving as the insulator region was selectively suppressed. When the surface treatment was performed on each of the substrates with the surface treatment agents in Examples 2 to 4, the minimum of the difference in water contact angle was 32.3° in Example 2. It is found from the results of these tests that as the basic nitrogen-containing compound (B), a quaternary ammonium compound was used, and thus the water repellency of the Al₂O₃ substrate was more suppressed.

### Examples 5A to 5C

### (Preparation of Surface Treatment Agent)

The contents of the compound (P) and the basic nitrogen-containing compound (B) described in table 4 below were evenly mixed with a solvent below, 0.001% by mass, 0.005% by mass and 0.010% by mass of oxalic acid (100% solid) were respectively added so that surface treatment agents for Examples 5A to 5C respectively having pHs of 10.97, 10.69 and 10.10 were prepared.

As the compound (P), P1 below was used.
P1: Octadecylphosphonic acid
As the basic nitrogen-containing compound (B), B4 below was used.
B4: 1,1,3,3-tetramethylguanidine
As the solvent, A1 below was used.
A1: Propylene glycol monomethyl ether

### (Measurement of Water Contact Angle)

As in Examples 1 to 4 and Comparative Examples 1 to 3, the surface treatment agents obtained were used, the pretreatment using the HF aqueous solution on the Al₂O₃ substrate and the Cu substrate and the surface treatment using the surface treatment agents on the substrates were performed and the water contact angle on each of the substrates after the surface treatment was measured. The difference in water contact angle on the Cu substrate and the Al₂O₃ substrate was calculated. The results are shown in table 4.

### (Measurement of Etching Rate)

The etching rates (nm/min) of the Al₂O₃ substrate and the Cu substrate were determined from a variation in the thickness of each of the substrates before and after the surface treatment using the surface treatment agents on the substrates, and when the variation was equal to or less than ±0.5 nm/min, it was evaluated to be “good” (indicated by a circle symbol (∘)). The results are shown in table 2.

TABLE 2

| | Compound | Compound | | | Water | | Difference | | |
|---|---|---|---|---|---|---|---|---|---|
| | (P) | (B) | | | contact | | in water | E.R. | |
| | Type/ | Type/ | Solvent | | angle (°) | | contact | (nm/min) | |
| | mass % | mass % | Type | pH | Al₂O₃ | Cu | angle (°) | Al₂O₃ | Cu |
| Example 5A | P1/0.05 | B4/0.058 | A1 | 10.97 | 64.2 | 86.9 | 22.7 | ∘ | ∘ |
| Example 5B | P1/0.05 | B4/0.058 | A1 | 10.69 | 54.7 | 79.7 | 25.0 | ∘ | ∘ |
| Example 5C | P1/0.05 | B4/0.058 | A1 | 10.10 | 47.5 | 71.8 | 24.3 | ∘ | ∘ |

It is found from the results of the water contact angle in table 2 that in the surface treatment agent based on Example 1, the pH was in a range of 10.1 to 10.97 and the difference in water contact angle was equal to or greater than 10°. It is also found from the results of the etching rates in table 2 that damage to each of the substrates was suppressed and a difference in water contact angle was not caused by the damage to the substrate.

### Examples 6 to 7

### (Preparation of Surface Treatment Agent)

The contents of the compound (P) and the basic nitrogen-containing compound (B) described in table 3 below were evenly mixed with a solvent below to prepare surface treatment agents for Examples 6 and 7.

As the compound (P), P1 below was used.
P1: Octadecylphosphonic acid
As the basic nitrogen-containing compound (B), B7 and B8 below were used.
B7: Tetramethylammonium fluoride
B8: Tetrabutylammonium fluoride
As the solvent, A1 below was used.
A1: Propylene glycol monomethyl ether

### (Measurement of Water Contact Angle)

As in Examples 1 to 4 and Comparative Examples 1 to 3, the surface treatment agents obtained were used, the pretreatment using the HF aqueous solution on the Al₂O₃ substrate and the Cu substrate and the surface treatment using the surface treatment agents on the substrates were performed and the water contact angle on each of the substrates after the surface treatment was measured. The difference in water contact angle on the Cu substrate and the Al₂O₃ substrate was calculated. The results are shown in table 3.

TABLE 3

| | | | | | Water | | Difference |
|---|---|---|---|---|---|---|---|
| | Compound (P) | Compound (B) | | | contact | | in water |
| | Type/ | Type/ | Solvent | | angle (°) | | contact |
| | mass % | mass % | Type | pH | Al₂O₃ | Cu | angle (°) |
| Example 6 | P1/0.05 | B7/0.047 | A1 | 8.83 | 14.8 | 98.6 | 83.8 |
| Example 7 | P1/0.05 | B8/0.13 | A1 | 8.45 | 21.4 | 94.3 | 72.9 |

It is found from the results in table 3 that when the surface treatment was performed on each of the substrates with the surface treatment agents in Examples 6 and 7, the minimum of the difference in water contact angle was 72.9° in Example 7. It is found from the results of these tests that a fluoride salt of a quaternary ammonium compound was used as the basic nitrogen-containing compound (B), and thus the water repellency of the Al₂O₃ substrate was extremely selectively suppressed.

### [Test 1 and Comparative Tests 1 and 2 of Surface Treatment and ALD Film Formation]

The surface treatment agent in Example 6 where the difference in water contact angle was large was used, test 1 of surface treatment and ALD film formation was performed by the following procedure on a SiO₂ substrate and a Cu substrate. The result of each test piece was evaluated on the assumption that the result was the result of a case where the metal region and the insulator region were included on the same substrate. In comparative test 1, the same procedure as in test 1 described above was used except that instead of the surface treatment agent in Example 6, the surface treatment agent in Comparative Example 1 was used, and thus surface treatment and ALD film formation were performed. In comparative test 2, the immersion in the surface treatment agent in step 3 of the procedure in comparative test 1 was performed only once before the first ALD cycle treatment.

### (Procedure)

1. The test piece including a SiO₂ region and a Cu region was subjected to cleaning treatment using dilute hydrofluoric acid for one minute.
2. The test piece after the treatment was rinsed with pure water and was then subjected to nitrogen blow.
3. The test piece after the blow was immersed in the surface treatment agent of Example 6 for one minute, was then cleaned with isopropanol while being stirred for one minute, was rinsed with pure water and was then subjected to nitrogen blow.
4. The ALD cycle treatment was performed 18 times under the following conditions.
Atomic layer deposition (ALD) device: AT-410 (made by Anric Technologies Inc.)
Chamber temperature: 150° C.
Precursor: Trimethylaluminum and H₂O
   5. Each time the cycle treatment was performed 18 times, steps 2 to 4 in the procedure were repeated, and the ALD cycle was performed a total of 144 times (18 times×8).
   6. For each of the test pieces after the cycle treatment was performed 18 times, 36 times and 144 times, how deeply the deposition of Al₂O₃ was formed was checked by X-ray fluorescence analysis. The results are shown in table 4.

TABLE 4

| | | | Thickness of | Thickness of | |
|---|---|---|---|---|---|
| | Surface | | film deposited | film deposited | Difference |
| Evaluation | treatment | Number of | on Cu region | on SiO₂ region | in thickness |
| test | agent | cycles | (nm) | (nm) | (nm) |
| Test 1 | Example 6 | 18 times | 0.3 | 2.0 | 1.7 |
| | | 36 times | 0.3 | 3.1 | 2.8 |
| | | 144 times | 0.3 | 9.1 | 8.8 |
| Comparative | Comparative | 18 times | 0.3 | 2.0 | 1.7 |
| test 1 | Example | 36 times | 0.3 | 2.1 | 1.8 |
| | | 144 times | 0.3 | 2.1 | 1.8 |
| Comparative | Comparative | 18 times | 0.3 | 2.0 | 1.7 |
| test 2 | Example 1 | 36 times | 0.4 | 3.5 | 3.1 |
| | | 144 times | 9.0 | 13.5 | 4.5 |

As shown in table 4, the treatment using the surface treatment agent of Example 6 was performed, and thus even after the 144 cycles, the selectivity in the ALD film formation was satisfactorily held, with the result that it is suggested that a contrast of about 10 nm can be made. On the other hand, in the composition of Comparative Example 1, even when the cycle was repeated, the thickness of the film was not increased, with the result that a contrast was lost even when the surface treatment conditions were changed. It is found from the results of these tests that the surface treatment agent according to the present invention is used, and thus it is possible not only to perform selective ALD film formation on the pattern substrate including the Cu region (pattern) and the Al₂O₃ region (pattern) but also to selectively increase the thickness of the film of Al₂O₃ on the pattern substrate including the Cu region and the SiO₂ region.

What is claimed is:

1. A surface treatment method for a surface of a substrate,
the surface comprising two or more regions,
the two or more regions comprising at least one metal region and at least one insulator region,
the at least one metal region and the at least one insulator region in the two or more regions being close to each other,
the metal region comprising a metal, the insulator region comprising one or more types of compounds selected from the group consisting of an oxide, a nitride, a carbide, a carbonitride, an oxynitride, an oxycarbonitride and an insulating resin,
the surface treatment method comprising:
reacting a compound (P), a basic nitrogen-containing compound (B), and the regions with each other such that a water contact angle on the metal region is greater by 10° or more with respect to a water contact angle on the insulator region close to the metal region,
wherein the compound (P) is represented by a general formula (P-1) below:
R¹—P(═O)(OR²)(OR³) (P-1)
wherein R¹ is an alkyl group, an alkoxy group, a fluorinated alkyl group or an optionally substituted aromatic hydrocarbon group and R² and R³ are each independently a hydrogen atom, an alkyl group, a fluorinated alkyl group or an optionally substituted aromatic hydrocarbon group.

2. The surface treatment method according to claim 1, wherein the basic nitrogen-containing compound (B) is selected from the group consisting of a quaternary ammonium compound, a pyridinium halide, a pyrrolidinium halide, a bipyridinium halide and an amine having pK_{b} of 2.5 or less or a salt thereof.

3. The surface treatment method according to claim 1, wherein the metal is one or more selected from the group consisting of copper, cobalt, aluminum, silver, nickel, titanium, gold, chromium, molybdenum, tungsten, ruthenium, titanium nitride and tantalum nitride, and the insulator is one or more types selected from the group consisting of aluminum oxide, titanium oxide, zirconium oxide, hafnium oxide, tantalum oxide, silicon oxide, fluorine-containing silicon oxide, carbon-containing silicon oxide, silicon nitride, boron nitride, silicon carbide, silicon carbonitride, silicon oxynitride and silicon oxycarbonitride.

4. The surface treatment method according to claim 1, wherein a water contact angle on the metal region after the reaction is equal to or greater than 70°.

5. A method of forming a region selective film on a substrate surface, the method comprising:
treating the substrate surface using the surface treatment method according to claim 1; and
forming a film by an atomic layer deposition method on the substrate surface subjected to the surface treatment,
wherein a larger amount of material of the film is deposited on the insulator region than on the metal region.

6. A one-component surface treatment agent used in the surface treatment method according to claim 1, the one-component surface treatment agent comprising:
the compound (P),
the basic nitrogen-containing compound (B), and
a solvent,
wherein the compound (P) is represented by the general formula (P-1) below:
R¹—P(═O)(OR²)(OR³) (P-1)
wherein R¹ is an alkyl group, an alkoxy group, a fluorinated alkyl group, or an optionally substituted aromatic hydrocarbon group and R² and R³ are each independently a hydrogen atom, an alkyl group, a fluorinated alkyl group, or an optionally substituted aromatic hydrocarbon group.

7. A two-component surface treatment agent used in the surface treatment method according to claim 1, the two-component surface treatment agent comprising:
a first surface treatment agent comprising the compound (P) and a solvent, and
a second surface treatment agent comprising the basic nitrogen-containing compound (B) and a solvent,
the compound (P) being represented by the general formula (P-1) below:
R¹—P(═O)(OR²)(OR³) (P-1)
wherein R¹ is an alkyl group, an alkoxy group, a fluorinated alkyl group or an optionally substituted aromatic hydrocarbon group and R² and R³ are each independently a hydrogen atom, an alkyl group, a fluorinated alkyl group or an optionally substituted aromatic hydrocarbon group.
